(19) United States
(12) Patent Application Publication
(10) Pub. No.: US 2012/0149315 A1
(43) Pub. Date: Jun. 14, 2012

(54) Detector Device, and Amplification Device, Transmission Device, and Communication Device Using the Detector Device

(75) Inventors: Akira Nagayama, Kunitachi-shi (JP); Yasuhiko Fukuoka, Soraku-gun (JP); Sadao Igarashi, Kawasaki-shi (JP)

(73) Assignee: KYOCERA CORPORATION, Kyoto-shi, Kyoto (JP)

(21) Appl. No.: 13/392,072

(22) PCT Filed: Aug. 25, 2010
(86) PCT No.: PCT/JP2010/064355

§ 371 Date: Feb. 23, 2012

(30) Foreign Application Priority Data
Aug. 27, 2009 (JP) 2009-196319

(51) Int. Cl. H04B 7/005; H03F 3/16; H04B 1/40; H03F 3/45

(52) U.S. Cl. 455/90.2; 330/69; 330/253; 455/127.3

(57) ABSTRACT

Provided is a detector device including: an amplifier (AMP1) for amplifying a voltage of an input electric signal and outputting the amplified electric signal; a first detector circuit (Det1) for outputting a first detection signal having a current corresponding to the voltage of the input electric signal; a second detector circuit (Det2) for outputting a second detection signal having a current corresponding to the voltage of the input electric signal; and a current summing circuit (SUM1) to which the first detection signal and the second detection signal are input, for outputting a third detection signal having a current value obtained by summing current values of the first detection signal and the second detection signal, in which an input signal to be detected is divided into two, one of the divided signals being input to the first detector circuit (Det1) and the other of the divided signals being input via the amplifier (AMP1) to the second detector circuit (Det2). Accordingly, a detector device having a wide dynamic range, and an amplification device, a transmission device, and a communication device using the detector device may be obtained.

### TECHNICAL FIELD

The present invention relates to a detector device, and an amplification device, a transmission device, and a communication device using the detector device. More particularly, the present invention relates to a detector device having a wide dynamic range, and an amplification device, a transmission device, and a communication device using the detector device.

### BACKGROUND ART

As a conventional detector device, a mixer including a differential amplifier is widely used. Further, a detector device using a diode is known (see, for example, Patent Literature 1).

### PRIOR ART DOCUMENT

### Patent Document

Patent Literature 1: JP 3-258121 A

### DISCLOSURE OF THE INVENTION

### Problems to be Solved by the Invention

However, only a dynamic range of about 10 dB may be obtained with a pair of differential amplifiers, and thus, in order to obtain a dynamic range of, for example, about 60 dB, it is necessary to use a lot of pairs of differential amplifiers, and there is a problem in that the circuit scale and the power consumption increase. Further, in the detector device proposed in Patent Literature 1, the dynamic range is widened by switching a plurality of resistors with a switch, but, as the input power varies exponentially, the detection voltage also varies exponentially, and there is a problem in that subsequent signal processing is difficult.

The present invention has been made in view of these problems of conventional technologies, and an object of the present invention is to provide a detector device having a wide dynamic range, and an amplification device, a transmission device, and a communication device using the detector device.

### Means for Solving the Problems

According to the present invention, there is provided a first detector device including: an amplifier for amplifying a voltage of an input electric signal and outputting the amplified electric signal; a first detector circuit of translinear type for outputting a first detection signal having a current corresponding to the voltage of the input electric signal; a second detector circuit of translinear type for outputting a second detection signal having a current corresponding to the voltage of the input electric signal; and a current summing circuit to which the first detection signal and the second detection signal are input, for outputting a third detection signal having a current value obtained by summing current values of the first detection signal and the second detection signal, in which an input signal to be detected is divided into two, one of the divided signals being input to the first detector circuit and the other of the divided signals being input via the amplifier to the second detector circuit.

A second detector device according to the present invention is the first detector device, in which the input signal includes differential signals.

A third detector device according to the present invention is the second detector device, in which: each of the first detector circuit and the second detector circuit comprises a first transistor, a second transistor, a third transistor, and a fourth transistor which are N-channel field-effect transistors and a fifth transistor, a sixth transistor, a seventh transistor, an eighth transistor, and a ninth transistor which are P-channel field-effect transistors; the first transistor and the fifth transistor include drain terminals connected to each other; the second transistor and the sixth transistor include drain terminals connected to each other; the third transistor and the seventh transistor include drain terminals connected to each other; the fourth transistor and the eighth transistor include drain terminals connected to each other; the first transistor includes a body terminal and a source terminal connected to each other; the second transistor includes a body terminal connected to the drain terminal of the first transistor; the second transistor and the third transistor include gate terminals connected to each other; the third transistor includes a body terminal connected to the drain terminal of the fourth transistor; the fourth transistor includes a body terminal and a source terminal connected to each other; the fifth transistor, the eighth transistor, and the ninth transistor include gate terminals connected to a drain terminal of the ninth transistor; the sixth transistor and the seventh transistor include gate terminals connected to the drain terminal of the sixth transistor; the first transistor, the second transistor, the third transistor, and the fourth transistor include source terminals connected to a reference potential, and the fifth transistor, the sixth transistor, the seventh transistor, the eighth transistor, and the ninth transistor include source terminals connected to a power supply potential; the drain terminal of the ninth transistor is connected via a resistor to the reference potential; one of the differential signals is input to a gate terminal of the fourth transistor and the other of the differential signals is input to a gate terminal of the first transistor; and the first detection signal or the second detection signal is output from a line which connects the drain terminal of the third transistor and the drain terminal of the seventh transistor to each other.

A fourth detector device according to the present invention is any one of the first to third detector devices further including a current-voltage converting circuit to which the third detection signal is input, for outputting a fourth detection signal having a voltage value which varies logarithmically with the current value of the third detection signal.

A first amplification device of the present invention includes: an amplifying portion for amplifying an input high frequency signal and outputting the amplified signal; the first detector device to which a part of the output signal of the amplifying portion is input, for outputting the third detection signal; and a control circuit to which the third detection signal is input, for outputting a control signal for controlling an amplification factor of the amplifying portion.

A second amplification device of the present invention includes: an amplifying portion for amplifying an input high frequency signal and outputting the amplified signal; the fourth detector device to which a part of the output signal of the amplifying portion is input, for outputting the fourth detection signal; and a control circuit to which the fourth detection signal is input, for outputting a control signal for controlling an amplification factor of the amplifying portion.

In a transmission device according to the present invention, an antenna is connected to a transmission circuit via the first amplification device or the second amplification device.

In a communication device according to the present invention, an antenna is connected to a transmission circuit via the first amplification device or the second amplification device, and a reception circuit is connected to the antenna.

### DISCLOSURE OF THE INVENTION

According to the present invention, a detector device having a wide dynamic range is obtained.

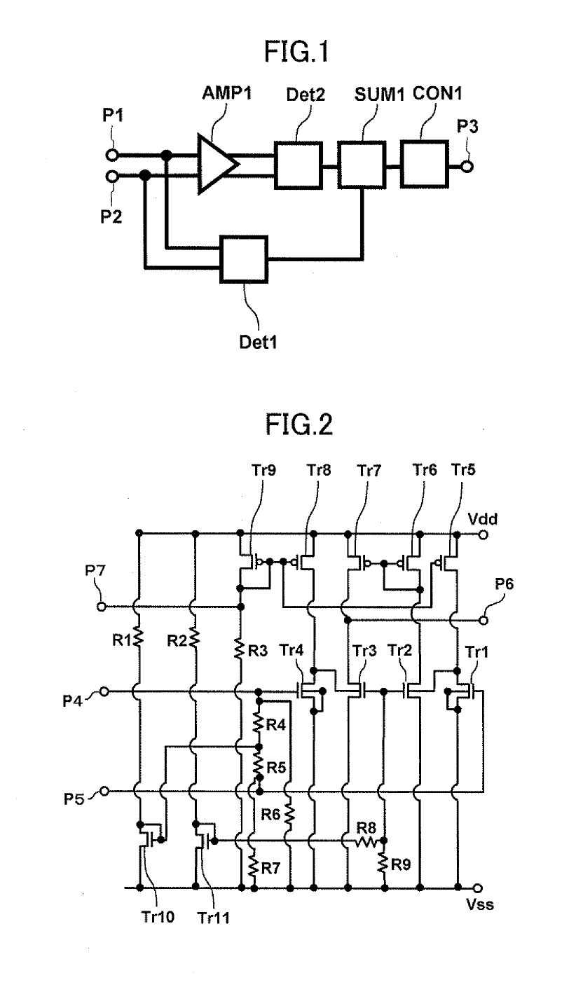

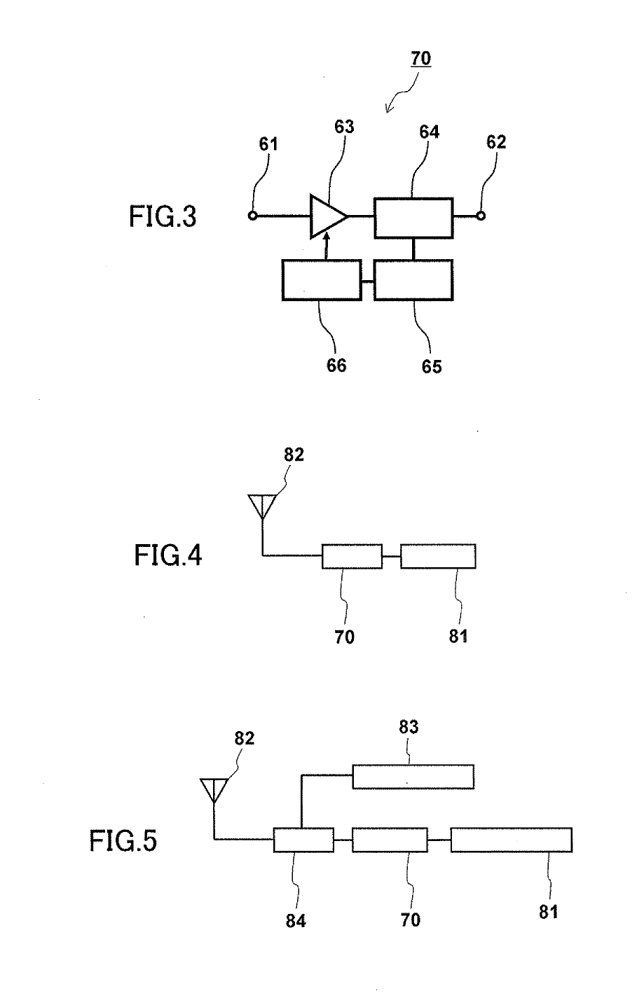

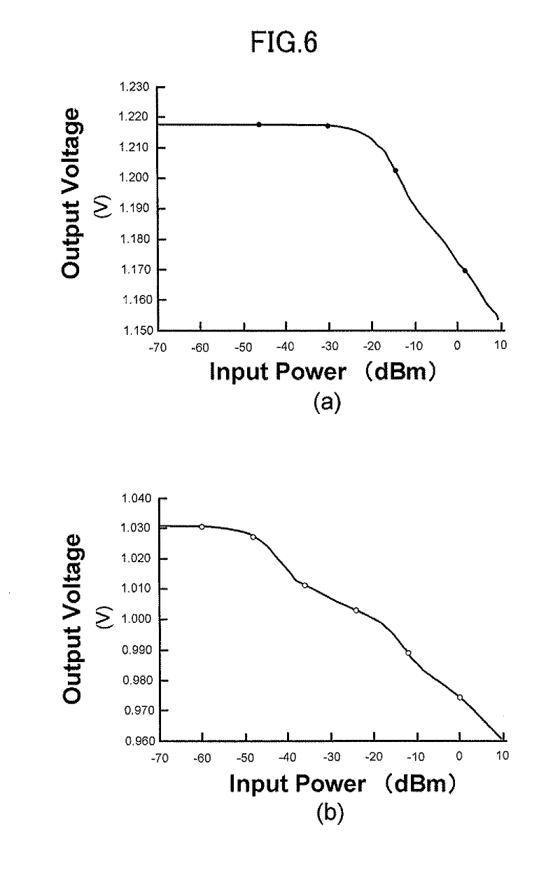

### BRIEF DESCRIPTION OF THE DRAWINGS

[FIG. 1] A block diagram schematically illustrating a detector device according to a first embodiment of the present invention.

[FIG. 2] A circuit diagram schematically illustrating an exemplary structure of each of a first detector circuit Det1 and a second detector circuit Det2 of FIG. 1.

[FIG. 3] A block diagram schematically illustrating an amplification device according to a second embodiment of the present invention.

[FIG. 4] A block diagram schematically illustrating a transmission device according to a third embodiment of the present invention.

[FIG. 5] A block diagram schematically illustrating a communication device according to a fourth embodiment of the present invention.

[FIG. 6] Graphs showing a simulation result of detection characteristics of the detector device according to the first embodiment of the present invention and detection characteristics of the first detector circuit Det1 and the second detector circuit Det2 used in the detector device.

### BEST MODE FOR CARRYING OUT THE INVENTION

In the following, a detector device, and an amplification device, a transmission device, and a communication device using the detector device according to the present invention are described in detail with reference to the attached drawings.

### First Embodiment

FIG. 1 is a block diagram illustrating a detector device according to a first embodiment of the present invention. FIG. 2 is a circuit diagram schematically illustrating an exemplary structure of each of a first detector circuit Det1 and a second detector circuit Det2 illustrated in FIG. 1.

As illustrated in FIG. 1, the detector device of this embodiment includes differential signal input terminals P1 and P2, an output terminal P3, an amplifier AMP1, the first detector circuit Det1, the second detector circuit Det2, a current summing circuit SUM1, and a current-voltage converting circuit CON1.

An input signal to be detected is input to the differential signal input terminals P1 and P2. One of the input differential signals is input to the first detector circuit Det1. The other of the input differential signals is, after being input to the amplifier AMP1 and voltage-amplified with a predetermined amplification factor, input to the second detector circuit Det2. The first detector circuit Det1 outputs a first detection signal having a current value corresponding to the voltage of the input electric signal. The second detector circuit Det2 outputs a second detection signal having a current value corresponding to the voltage of the input electric signal. The first detection signal and the second detection signal are input to the current summing circuit SUM1. The current summing circuit SUM1 sums the first detection signal and the second detection signal, and outputs a third detection signal having a current value obtained by summing the current value of the first detection signal and the current value of the second detection signal. The third detection signal is input to the current-voltage converting circuit CON1. The current-voltage converting circuit CON1 outputs to the output terminal P3 a fourth detection signal having a voltage value which varies logarithmically with the current value of the third detection signal.

Both the first detector circuit Det1 and the second detector circuit Det2 are detector circuits of translinear type, and have the same circuit structure illustrated in FIG. 2 and the same electrical characteristics. The first detector circuit Det1 and the second detector circuit Det2 output the first detection signal and the second detection signal, respectively, which have currents that vary approximately linearly with the voltage when the voltage of an input signal is within a detectable range, and that are gradually saturated when the voltage of an input signal exceeds a maximum detectable value. The current summing circuit SUM1 is a circuit which outputs an electric signal having a current obtained by summing the currents of the two input signals, and, for example, a circuit which uses an operational amplifier is well known. The current-voltage converting circuit CON1 is a circuit which has the current-voltage conversion function and outputs a signal having a voltage value that varies logarithmically with the input current value, and may be formed by, for example, combining an existing current-voltage converting circuit and an existing logarithmic amplifying circuit. As the current-voltage converting circuit and the logarithmic amplifying circuit, circuits which use an operational amplifier are known.

According to the detector device of this embodiment having the structure described above, one of the input signals to be detected is input to the first detector circuit Det1, and the other of the input signals is, after being input to the amplifier AMP1 and amplified with the predetermined amplification factor, input to the second detector circuit Det2.

When the voltage of the input signal is smaller than a minimum detectable voltage of the first detector circuit Det1 and the voltage of the signal amplified by the amplifier AMP1 is within the detectable range of the second detector circuit Det2, the first detection signal from the first detector circuit Det1 is not output, but the second detection signal having a current value corresponding to the voltage of the input signal is output from the second detector circuit Det2. Then, the third detection signal having a current value corresponding to the voltage of the input signal is output from the current summing circuit SUM1, and the fourth detection signal having a voltage value corresponding to the voltage of the input signal is output from the current-voltage converting circuit CON1.

When the voltage of the input signal is within the detectable range of the first detector circuit Det1 and the voltage of the signal amplified by the amplifier AMP1 is within, the detectable range of the second detector circuit Det2, the first detection signal and the second detection signal each having a current value corresponding to the voltage of the input signal are output. Then, the first detection signal and the second detection signal are summed, the third detection signal having a current value corresponding to the voltage of the input signal is output from the current summing circuit SUM1, and the fourth detection signal having a voltage value corresponding to the voltage of the input signal is output from the current-voltage converting circuit CON1.

When the voltage of the input signal is within the detectable range of the first detector circuit Det1 and the voltage of the input signal amplified by the amplifier AMP1 is larger than the maximum detectable value of the second detector circuit Det2, the first detection signal has a current value corresponding to the voltage of the input signal while the second detection signal is saturated to have a fixed current value irrespective of the voltage of the input signal. Then, the first detection signal and the second detection signal are summed, the third detection signal having a current value corresponding to the voltage of the input signal is output from the current summing circuit SUM1, and the fourth detection signal having a voltage value corresponding to the voltage of the input signal is output from the current-voltage converting circuit CON1.

In this way, the voltage range of a detectable input signal is increased, and thus, a detector device having a wide dynamic range is obtained. Note that, through setting of the amplification factor of the amplifier AMP1 so as to be equal to the ratio of the minimum value to the maximum value in the detectable voltage range of the first detector circuit Det1 and the second detector circuit Det2, at the moment when the second detection signal output from the second detector circuit Det2 is saturated, the first detection signal corresponding to the input signal may be caused to be output from the first detector circuit Det1. Therefore, a continuously detectable dynamic range becomes the maximum, and a detector device having a wide dynamic range which is obtained by directly summing the dynamic range of the first detector circuit Det1 and the dynamic range of the second detector circuit Det2 is obtained.

Further, in the detector device according to this embodiment, the first detection signal and the second detection signal have current values corresponding to the voltage of the input electric signal, respectively, and a third detection signal is generated by summing these two current values at the summing circuit SUM1. For example, when the voltage values of the first detection signal and the second detection signal are used and the third detection signal is obtained by summing the voltage values, a compensating circuit such as a voltage reference circuit or a temperature compensating circuit is necessary in order to compute the sum of the voltages with high precision. On the other hand, in the detector device according to this embodiment, since the current values of the first detection signal and the second detection signal are summed, and compared with the case in which the voltage values are summed, the sum can be computed more easily and precisely, and thus, the current summing circuit SUM1 which has a simple structure may be used. This enables obtainment of a detector device which has a simple structure and which is small.

FIG. 2 is a circuit diagram illustrating the structure of the first detector circuit Det1 and the second detector circuit Det2 in the detector device illustrated in FIG. 1. As illustrated in FIG. 2, each of the first detector circuit Det1 and the second detector circuit Det2 includes first to fourth transistors Tr1 to Tr4 each including a source terminal connected to a reference potential (ground potential) Vss, fifth to ninth transistors Tr5 to Tr9 each including a source terminal connected to a power supply potential, and tenth and eleventh transistors Tr10 and Tr11. Note that, the first to fourth, tenth, and eleventh transistors are N-channel field-effect transistors while the fifth to ninth transistors are P-channel field-effect transistors.

A drain terminal of the first transistor Tr1 and a drain terminal of the fifth transistor Tr5 are connected to each other, and a drain terminal of the second transistor Tr2 and a drain terminal of the sixth transistor Tr6 are connected to each other. A drain terminal of the third transistor Tr3 and a drain terminal of the seventh transistor Tr7 are connected to each other, and a drain terminal of the fourth transistor Tr4 and a drain terminal of the eighth transistor Tr8 are connected to each other. A drain terminal of the ninth transistor Tr9 is connected via a resistor R3 to the reference potential (ground potential) Vss.

Further, gate terminals of the fifth, eighth, and ninth transistors Tr5, Tr8, and Tr9 are connected to the drain terminal of the ninth transistor Tr9 to form a current mirror circuit. Gate terminals of the sixth and seventh transistors Tr6 and Tr7 are connected to the drain terminal of the sixth transistor Tr6 to form another current mirror circuit.

Further, a body terminal of the first transistor Tr1 is connected to the source terminal of the first transistor Tr1. A body terminal of the second transistor Tr2 is connected to the drain terminal of the first transistor Tr1. A body terminal of the third transistor Tr3 is connected to the drain terminal of the fourth transistor Tr4. A body terminal of the fourth transistor Tr4 is connected to the source terminal of the fourth transistor Tr4. A gate terminal of the second transistor Tr2 is connected to a gate terminal of the third transistor Tr3.

Further, a drain terminal of the tenth transistor Tr10 is connected via a resistor R1 to the power supply voltage and a source terminal of the tenth transistor Tr10 is connected to the ground potential. A gate terminal and the drain terminal of the tenth transistor Tr10 are connected to each other. In a circuit structure described above, a gate potential of the tenth transistor Tr10 is determined based on the value of resistor R1. The gate terminal of the tenth transistor Tr10 is connected via a series connection circuit of a resistor R4 and a resistor R6 to the reference potential (ground potential) Vss, and is connected via a series connection circuit of a resistor R5 and a resistor R7 to the reference potential (ground potential) Vss. Further, a connection node between the resistor R5 and the resistor R7 is connected to a gate terminal of the first transistor Tr1 and a connection node between the resistor R4 and the resistor R6 is connected to a gate terminal of the fourth transistor Tr4. The resistor R4 and the resistor R6 form a voltage dividing circuit and the resistor R5 and the resistor R7 form a voltage dividing circuit, and thus, bias voltages obtained by dividing the gate potential of the tenth transistor Tr10 are supplied to the gate terminal of the first transistor Tr1 and the gate terminal of the fourth transistor Tr4, respectively.

Similarly, a drain terminal of the eleventh transistor Tr11 is connected via a resistor R2 to the power supply voltage and a source terminal of the eleventh transistor Tr11 is connected to the ground potential. A gate terminal and the drain terminal of the eleventh transistor Tr11 are connected to each other. In the circuit structure described above, a gate potential of the eleventh transistor Tr11 is determined based on the value of the resistor R2. The gate terminal of the eleventh transistor Tr11 is connected via a series connection circuit of a resistor R8 and a resistor R9 to the reference potential (ground potential) Vss. Further, a connection node between the resistor R8 and the resistor R9 is connected to the gate terminal of the second transistor Tr2 and the gate terminal of the third transistor Tr3. The resistor R8 and the resistor R9 form a voltage dividing circuit, and thus, bias voltages obtained by dividing the gate potential of the eleventh transistor Tr11 are supplied to the gate terminal of the second transistor Tr2 and the gate terminal of the third transistor Tr3, respectively.

Further, the source terminal of the ninth transistor Tr9 is connected to the power supply voltage and the drain terminal of the ninth transistor Tr9 is connected via the resistor R3 to the reference potential (ground potential) Vss. Therefore, a reference current Ib which passes through the ninth transistor Tr9 is determined based on the resistor R3, and the reference current Ib is copied to each of the fifth transistor Tr5 and the eighth transistor Tr8 which form the current mirror circuit. The drain terminal of the ninth transistor Tr9 is connected to a reference current input terminal P7. The reference current Ib may be adjusted by a reference current which is input from the reference current input terminal P7.

Further, an input terminal P4 is connected to the gate terminal of the fourth transistor Tr4, an input terminal P5 is connected to the gate terminal of the first transistor Tr1, and an output terminal P6 is connected to a line which connects the drain terminal of the third transistor Tr3 and the drain terminal of the seventh transistor Tr7 to each other. One of the differential signals is input via the input terminal P4 to the gate terminal of the fourth transistor Tr4 and the other of the differential signals is input via the input terminal P5 to the gate terminal of the first transistor Tr1. The first detection signal or the second detection signal is output via the output terminal P6 from the line which connects the drain terminal of the third transistor Tr3 and the drain terminal of the seventh transistor Tr7 to each other.

In this way, a voltage Vp of one of the differential input signals which is supplied to the input terminal P4 and a bias voltage Vb from the dividing circuit including the resistor R4 and the resistor R6 are applied to the gate of the fourth transistor Tr4. Further, a voltage Vn of the other of the differential input signals which is supplied to the input terminal P5 and a bias voltage Vb from the dividing circuit including the resistor R5 and the resistor R7 are applied to the gate of the first transistor Tr1 A bias voltage Vc is applied from the dividing circuit including the resistor R8 and the resistor R9 to the gate of the second transistor Tr2 and to the gate of the third transistor Tr3.

In the first detector circuit Det1 and the second detector circuit Det2 which are of the translinear type and are structured as described above, when the drain terminal of the first transistor Tr1 and the body terminal of the second transistor Tr2 are connected to each other, as a drain current I2 of the second transistor Tr2, a current is obtained which is proportional to Vb, Vc, and Vp as expressed by the following Equation (1).

I3∝Ib·exp(Vb−Vc)·exp(Vn) (1)

Similarly, when the drain terminal of the fourth transistor Tr4 and the body terminal of the third transistor Tr3 are connected to each other, as a drain current I2 which passes through the third transistor Tr3, a current is obtained which is proportional to Vb, Vc, and Vp as expressed by the following Equation (2).

I2∝Ib·exp(Vb−Vc)·exp(Vp) (2)

Here, the drain current I2 of the second transistor Tr2 is copied by the current mirror circuit including the sixth and seventh transistors Tr6 and Tr7, and hence a drain current of the seventh transistor Tr7 becomes equal to I2. Therefore, at a connection node between the drain terminal of the third N-channel field-effect transistor Tr3 and the drain terminal of the seventh transistor Tr7, according to the Kirchhoff's current law, a current of I2-I3 flows into the output terminal P6. It follows that the following Equation (3) is obtained.

I2−I3∝Ib·exp(Vb−Vc)·{exp(Vn)−exp(Vp)} (3)

Using the Taylor expansion and Vp=−Vn (because the input signals are differential signals), the right side of the Equation (3) may be approximated as −2Ib·exp(Vb−Vc)·Vp. From this, it can be seen that the first detection signal and the second detection signal which have the current I2-I3 that varies approximately linearly with the voltage Vp of the input electric signal may be obtained.

Further, when the bias voltage Vb which is applied to the gate terminal of the first transistor Tr1 and to the gate terminal of the fourth N-channel field-effect transistor Tr4, the bias voltage Vc which is applied to the gate terminal of the second transistor Tr2 and to the gate terminal of the third transistor Tr3, and the reference current Ib are appropriately adjusted, the current gain may be adjusted.

According to the detector device of this embodiment, the third detection signal obtained by current summing the first detection signal and the second detection signal which have currents that vary approximately linearly with the voltage of the input electric signal is input to the current-voltage converting circuit CON1, and the fourth detection signal having a voltage value which varies logarithmically with the current value of the third detection signal is output. Therefore, the detector device of this embodiment may output the fourth detection signal having a voltage which varies approximately logarithmically with the voltage of an input signal to be detected. This enables obtainment of a detector device having excellent characteristics that can detect an input signal having a voltage which varies exponentially and greatly and that, even when the voltage of the input signal varies exponentially and greatly, prevents variations in the voltage of an output signal from becoming too large.

### Second Embodiment

FIG. 3 is a circuit diagram illustrating an amplification device according to a second embodiment of the present invention.

As illustrated in FIG. 3, the amplification device of this embodiment includes an input terminal 61, an output terminal 62, an amplifying portion 63, a distribution circuit 64, a detector device 65 as illustrated in FIG. 1, and a control circuit 66. The amplifying portion 61 amplifies a high frequency signal input from the input terminal and outputs the amplified signal. The distribution circuit 64 passes the output signal from the amplifying portion 61 toward the output terminal 62, and a part of the signal is distributed to be input to the detector device 65. The detector device 65 outputs a fourth detection signal having a voltage which is logarithmically proportional to the voltage of an input electric signal. The control circuit 66 outputs a control signal for controlling the amplification factor of the amplifying portion 63 based on the input fourth detection signal. Based on the control signal input to the amplifying portion 63, the gain of the amplifying portion 63 is controlled.

According to the amplification device of this embodiment which is structured as described above, the amplification factor of the amplifying portion 63 may be controlled based on amplitude data obtained by detecting an output signal from the amplifying portion 63, and thus, the amplitude of the output signal from the amplifying portion 63 may be adjusted to a desired value. Further, a wide range of output signals can be detected only by one detector device 65 which has a wide dynamic range, is small, and has a simple structure, and thus, an amplification device which is small and has a simple structure can be obtained.

### Third Embodiment

FIG. 4 is a block diagram illustrating a transmission device according to a third embodiment of the present invention. As illustrated in FIG. 4, in the transmission device of this embodiment, a transmission circuit 81 is connected to an antenna 82 via an amplification device 70 as illustrated in FIG. 3. Note that, the input terminal 61 of the amplification device 70 illustrated in FIG. 3 is connected to the transmission circuit 81 and the output terminal 62 of the amplification device 70 is connected to the antenna 82. According to the transmission device of this embodiment structured as described above, a transmission signal which is output from the transmission circuit 81 may be amplified using the amplification device 70 which is small and has a simple structure, and thus, a transmission device which is small and has a simple structure can be obtained.

### Fourth Embodiment

FIG. 5 is a block diagram illustrating an exemplary structure of a communication device according to a fourth embodiment of the present invention. As illustrated in FIG. 5, in the communication device of this embodiment, the transmission circuit 81 is connected via the amplification device 70 illustrated in FIG. 3 to the antenna 82, and a reception circuit 83 is connected to the antenna 82. Further, an antenna duplexer circuit 84 is inserted between the antenna 82 and the transmission circuit 81 and between the antenna 82 and the reception circuit 83. Note that, the input terminal 61 of the amplification device 70 illustrated in FIG. 3 is connected to the transmission circuit 81 and the output terminal 62 of the amplification device 70 is connected to the antenna duplexer circuit 84. According to the communication device of this embodiment structured as described above, a transmission signal which is output from the transmission circuit 81 may be amplified using the amplification device 70 which is small and has a simple structure, and thus, a transmission device which is small and has a simple structure can be obtained.

### EXAMPLE

Next, a specific example of the detector device according to the present invention is described. The electrical characteristics of the detector device of the first embodiment illustrated in FIG. 1 were calculated by circuit simulation. With regard to the conditions of the calculation, the frequency was 0.8 GHz and the input signal power was from −70 dBm to +10 dBm. Both the P-channel field-effect transistors and the N-channel field-effect transistors were MOSFETs.

The result is shown in FIG. 6(b). The result of a simulation of electrical characteristics of a circuit formed of only the first detector circuit Det1 or the second detector circuit Det2 and the current-voltage converting circuit CON1 connected to an output side thereof is shown in FIG. 6(a). In the graphs of FIGS. 6(a) and 6(b), the horizontal axis denotes the electric power of the input signal, while the vertical axis denotes the voltage of the output signal. According to the graph of FIG. 6(a), when the input signal power is +10 dBm to −20 dBm, the output voltage increases approximately linearly, and after that, the output voltage is saturated in the end. From this, it can be seen that each of the first detector circuit Det1 and the second detector circuit Det2 having the structure illustrated in FIG. 2 can carry out detection in a range of +10 dBm to −20 dBm, and has a wide input dynamic range of 30 dB. It can also be seen that variations in the output voltage are suppressed against the input power which varies exponentially and greatly.

Further, according to the graph of FIG. 6(b), the output voltage varies approximately linearly when the electric power of the input signal is +10 dBm to −50 dBm. From this, it can be seen that the detector device having the structure illustrated in FIG. 1 can carry out detection in a range of +10 dBm to −50 dBm, and has an input dynamic range of 60 dB. It can also be seen that variations in the output voltage are suppressed against the input power which varies exponentially and greatly.

From these results, it can be seen that, with use of two completely identical detector circuits each having a wide input dynamic range of 30 dB, a detector device having a still wider input dynamic range of 60 dB can be obtained. It can also be seen that a detector device capable of suppressing variations in the output voltage with against the input power which varies exponentially and greatly may be obtained. Thus, the effectiveness of the present invention is verified.

### REFERENCE SIGNS LIST

Tr1: first transistor
Tr2: second transistor
Tr3: third transistor
Tr4: fourth transistor
Tr5: fifth transistor
Tr6: sixth transistor
Tr7: seventh transistor
Tr8: eighth transistor
Tr9: ninth transistor
Det1: first detector circuit
Det2: second detector circuit
AMP1: amplifier
Vdd: power supply voltage
Vss: ground potential
63: amplifying portion
65: detector device
66: control circuit
70: amplification device
81: transmission circuit
82: antenna
83: reception circuit

1. A detector device, comprising:
an amplifier for amplifying a voltage of an input electric signal and outputting the amplified electric signal;
a first detector circuit of translinear type for outputting a first detection signal having a current corresponding to the voltage of the input electric signal;
a second detector circuit of translinear type for outputting a second detection signal having a current corresponding to the voltage of the input electric signal; and
a current summing circuit to which the first detection signal and the second detection signal are input, for outputting a third detection signal having a current value obtained by summing current values of the first detection signal and the second detection signal,
wherein an input signal to be detected is divided into two, one of the divided signals being input to the first detector circuit and the other of the divided signals being input via the amplifier to the second detector circuit.

2. The detector device according to claim 1, wherein the input signal comprises differential signals.

3. The detector device according to claim 2, wherein:
each of the first detector circuit and the second detector circuit comprises a first transistor, a second transistor, a third transistor, and a fourth transistor which are N-channel field-effect transistors and a fifth transistor, a sixth transistor, a seventh transistor, an eighth transistor, and a ninth transistor which are P-channel field-effect transistors;
the first transistor and the fifth transistor include drain terminals connected to each other;
the second transistor and the sixth transistor include drain terminals connected to each other;
the third transistor and the seventh transistor include drain terminals connected to each other;
the fourth transistor and the eighth transistor include drain terminals connected to each other;
the first transistor includes a body terminal and a source terminal connected to each other;
the second transistor includes a body terminal connected to the drain terminal of the first transistor;
the second transistor and the third transistor include gate terminals connected to each other;
the third transistor includes a body terminal connected to the drain terminal of the fourth transistor;
the fourth transistor includes a body terminal and a source terminal connected to each other;
the fifth transistor, the eighth transistor, and the ninth transistor include gate terminals connected to a drain terminal of the ninth transistor;
the sixth transistor and the seventh transistor include gate terminals connected to the drain terminal of the sixth transistor;
the first transistor, the second transistor, the third transistor, and the fourth transistor include source terminals connected to a reference potential, and the fifth transistor, the sixth transistor, the seventh transistor, the eighth transistor, and the ninth transistor include source terminals connected to a power supply potential;
the drain terminal of the ninth transistor is connected via a resistor to the reference potential;
one of the differential signals is input to a gate terminal of the fourth transistor and the other of the differential signals is input to a gate terminal of the first transistor; and
the first detection signal or the second detection signal is output from a line which connects the drain terminal of the third transistor and the drain terminal of the seventh transistor to each other.

4. The detector device according to claim 1, further comprising a current-voltage converting circuit to which the third detection signal is input, for outputting a fourth detection signal having a voltage value which varies logarithmically with the current value of the third detection signal.

5. An amplification device, comprising:
an amplifying portion for amplifying an input high frequency signal and outputting the amplified signal;
the detector device according to claim 1 to which a part of the output signal of the amplifying portion is input, for outputting the third detection signal; and
a control circuit to which the third detection signal is input, for outputting a control signal for controlling an amplification factor of the amplifying portion.

6. An amplification device, comprising:
an amplifying portion for amplifying an input high frequency signal and outputting the amplified signal;
the detector device according to claim 4 to which a part of the output signal of the amplifying portion is input, for outputting the fourth detection signal; and
a control circuit to which the fourth detection signal is input, for outputting a control signal for controlling an amplification factor of the amplifying portion.

7. A transmission device, comprising:
an antenna;
the amplification device according to claim 6; and
a transmission circuit connected to the antenna via the amplification device.

8. A communication device, comprising:
an antenna;
the amplification device according to claim 6;
a transmission circuit connected to the antenna via the amplification device; and
a reception circuit connected to the antenna.
